(19) United States
(12) Patent Application Publication
(10) Pub. No.: US 2025/0354295 A1
(43) Pub. Date: Nov. 20, 2025

(54) A DIAMOND MICROPARTICLES BASED PHYSICAL UNCLONABLE FUNCTIONAL MATERIAL, PREPARATION METHOD, AND USE THEREOF

(71) Applicants: Versitech Limited, Pokfulam (HK); Dongguan Institute of Opto-electronics, Peking University, Dongguan, Guangdong (CN)

(72) Inventors: Zhiqin Chu, Pokfulam (HK); Tongtong Zhang, Pokfulam (HK); Qi Wang, Dongguan, Guangdong (CN); Zhongqiang Wang, Dongguan, Guangdong (CN)

(21) Appl. No.: 18/876,300

(22) PCT Filed: May 23, 2023
(86) PCT No.: PCT/CN2023/095744

§ 371 Date: Dec. 18, 2024

(30) Foreign Application Priority Data
Jul. 15, 2022 (CN) 202210835536.X

(51) Int. Cl. C30B 29/04; C09K 11/65; C30B 25/10; C30B 25/18; G06K 19/06; G09F 3/02

(52) U.S. Cl. CPC C30B 29/04; C09K 11/65; C30B 25/105; C30B 25/186; G06K 19/06028; G06K 19/06037; G09F 3/02; G09F 2003/0208

(57) ABSTRACT

The present invention provides a nanodiamond based physical unclonable functional material, preparation method and applications thereof, comprising a single-crystal silicon substrate and nanodiamond with silicon vacancy color centers grown in situ thereon. The preparation method of nanodiamond particles on the silicon substrate is a stochastic process, which is an essential feature for manufacturing physical unclonable functional labels. The present invention uses scattering spectrum of nanodiamond, the morphological characteristics, and spatial position relationships as fingerprint information for the physical unclonable functional material. Due to the extreme heat resistance, mechanical, chemical and light stability of diamond material. The highly robust label of the present invention can satisfy the requirements of many practical applications in various environments. The present invention has huge applications. The present invention has real commercial value in the anti-counterfeiting market for electronic components, medical packaging, vehicles, luxury goods, etc.

### FIELD OF TECHNOLOGY

The invention relates to a physical unclonable function material based on diamond microparticles, its preparation method, and application.

### BACKGROUND TECHNOLOGY

Counterfeiting is becoming increasingly rampant around the world and is prevalent in the manufacturing of various products from daily consumer goods to pharmaceuticals and high-tech products. It seriously affects financial security, national security, and even threatens human health. To date, various anti-counterfeiting strategies have been developed to prevent counterfeiting, including watermarks, holograms, barcodes, and QR codes. However, most of these tags are manufactured through a repeatable deterministic process, which makes the encoded information vulnerable to forgery attacks by third parties with relevant expertise. Therefore, in response to the growing global counterfeiting problem, there is an urgent need to design and develop unbreakable anti-counterfeiting labels.

One promising approach that has recently attracted attention involves utilizing security tags with physical unclonable function (PUF). PUF is a hardware security technology that on receipt of an excitation signal, it will generate an unclonable and unique response signal that is unique and random. Because PUF relies on the uniqueness and randomness of its own physical microstructure, PUF is unpredictable and uncontrollable, making it virtually impossible to copy or clone that hardware structure. To date, a variety of materials (e.g., photonic crystals, metal nanoparticles, semiconductor nanoparticles, DNA nanostructures, hydrogels, upconversion nanoparticles, etc.) and fabrication methods (e.g., drop coating, spin coating, self-assembly, inkjet printing, etc.) have been developed to achieve PUF for anti-counterfeiting.

At present, PUF mainly includes optical PUF and electrical PUF. The input and output of electrical PUF are simple electrical signals, which can be attacked by machine learning. The excitation response can be modeled and replicated. It has poor security. Due to the excellent optical properties of the light-emitting components, optical PUFs have attracted increasing attention. Because it can regulate the optical characteristics of luminescent components in multiple dimensions, such as fluorescence color, intensity and lifetime values, it has inherent randomness, controllability and diversity. For example, the luminescence of these components (such as quantum dots, perovskite materials, polymer dots, upconversion nanoparticles, plasmonic nanoparticles, phosphors, and lanthanide complexes) can be induced by a series of external stimuli (light, heat, chemicals and mechanical forces), making them ideal materials for advanced cryptography. Despite the undoubted importance, most optical PUFs exhibit unsatisfactory stability in complex environments (e.g., high temperature, strong acid, strong alkali, UV, mechanical scratching, etc.). Furthermore, most of them are produced using wet chemical synthesis in solution, which may be incompatible with microelectronic devices and may adversely affect the primary product functionality. Therefore, the development of new and reliable PUF labels with mass production process compatibility is expected for the promotion of the next-generation anti-counterfeiting technologies, its development and practical application thereof.

In recent years, diamond materials have been widely used in various fields due to their special chemical inertness, excellent mechanical strength, high temperature stability and other characteristics. At the same time, various luminescent color centers in diamond crystals, such as nitrogen vacancy (NV) color centers and silicon vacancy (SiV) color centers, have also attracted widespread attention in multiple application fields due to their unique optical and spectral properties. At the same time, the surface chemical properties, shape and geometric dimensions of diamond materials can be improved through its synthesis methods (such as high pressure, high temperature and chemical vapor deposition technology, etc.) and other post-processing methods (such as surface modification, reactive ion etching and air oxidation) for adjustment. Therefore, the optical properties of color centers embedded within diamond crystals are sensitive to the surface chemistry, structure, and shape, which are difficult to accurately clone or forge. In particular, silicon vacancy color centers around the 737 nm range exhibit near-infrared (NIR) light emission that is invisible to the naked eye but can be captured by most commercial cameras, thereby reducing the difficulty of distinguishing confidential information from interference information. Therefore, those silicon vacancies in the diamond with NIR emission color centers have great potential in optical PUF tags.

U.S. Pat. No. 10,685,199B2 discloses the implementation of the orientation information of the nitrogen vacancy color center in nanodiamond to generate a unique anti-counterfeiting code. The preparation method is to coat a suspension of diamond particles on the surface of an object, or to mix the suspension of diamond particles into related materials and form an object from the material. The technique requires advanced microscopy instrumentation to read the orientation associated with the nitrogen-vacancy color centers in nanodiamonds. Based on this technology, nitrogen-vacancy color centers of nanodiamonds are used as anti-counterfeiting materials for advanced security services.

In addition, some scholars have proposed using nitrogen vacancies in diamond as a PUF signal readout analysis technology, but have not taught the use of diamond particles themselves as PUF construct materials (J. Appl. Phys. 2020, 127, 203904, PUFs enabled by an array of randomly magnetized micrometer-sized ferromagnetic bars (micromagnets), the magnetic polarity of each micromagnet is analyzed by NV centers in diamond).

With the development of chemical vapor deposition (CVD) and controllable doping technology, it has become possible to grow high-quality, large-area diamond particles containing different color centers on various substrates at relatively low cost. The position, size and shape of diamond particles grown by chemical vapor deposition are highly dependent on various parameters of chemical vapor deposition technology, such as seeding, nucleation and growth processes. These are highly random (non-deterministic) processes, and are essential requirements for manufacturing PUF labels. However, their robustness in complex working environments must be continuously improved in order to suit practical applications.

### DESCRIPTION OF THE INVENTION

Therefore, the object of the present invention is to provide a kind of nanodiamond particles containing silicon vacancy color centers as a robust physical unclonable functional material for use in optical anti-counterfeiting systems.

The inventor of the present invention remarkably invented nanodiamonds prepared using a salt-assisted air oxidation high-pressure high-temperature (HPHT) method, when used as seeds for chemical vapor deposition, can heterogeneously grow diamond micro-particles on a silicon substrate. The nanodiamond particles are capable of emitting ultra-stable, high-strength, and adjustable 1) silicon vacancy color center photoluminescence (PL) and 2) light scattering signals. It is thereby observable that the photoluminescence intensity of silicon vacancy color centers and the light scattering pattern and spectrum of nanodiamond particles can make large encoding capacity multidimensional PUF tags possible. In addition, the inventor also verified that this nanodiamond particles based PUF material is able to maintain ultra-high stability under the influence of harsh chemical environments, high temperatures, mechanical wear and ultraviolet light irradiation. The present invention can provide materials which have extremely high randomness, multi-mode encryption capability and excellent robustness, showing great potential for use as anti-counterfeiting labels in various fields.

Based on the above findings, a first aspect of the present invention provides a nanodiamond particles based physical unclonable functional material, wherein the physical unclonable functional material comprises: a monocrystalline silicon substrate having nanodiamond particles with silicon vacancy color centers grown in situ thereon.

In a preferred embodiment of the present invention, the nanodiamond particles with silicon vacancy color centers are grown on the monocrystalline silicon substrate by a chemical vapor deposition method. Preferably, in the chemical vapor deposition method, nanodiamonds treated with salt-assisted air oxidation are used as seed crystals.

In a nanodiamond particles based physical unclonable functional material of an embodiment of the present invention, the salt-assisted air oxidation treatment comprises mixing nanodiamond particles with soluble salts and heating the mixture in the air at 200 to 900° C. for 1 minute to 24 hours. Preferably, the soluble salt is sodium chloride. Preferably, the mass ratio of the nanodiamond particles to the soluble salt is 1:0.1˜10.

In a physical unclonable functional material of an embodiment of the present invention, the particle size of the nanodiamond particles is between 50 and 100,000 nm, and preferably from 100 to 10,000 nm.

Wherein the particle size of the nanodiamond particles used as the chemical vapor deposition seed crystals is between 1 and 500 nm, and preferably from 5 to 100 nm.

In a nanodiamond particles based physical unclonable functional material of an embodiment of the present invention, the growth surface of the monocrystalline silicon substrate is a (100) crystal plane.

In a nanodiamond particles based physical unclonable functional material of an embodiment of the present invention, the nanodiamond particles are adapted to cover 0.1%˜100% surface of the monocrystalline silicon substrate, and preferably 10 to 50%.

FIG. 1 shows the structure (a) and the energy level (b) of the silicon vacancy color center in a diamond crystal cell of a nanodiamond particles based physical unclonable functional material of the present invention. The silicon vacancy color center in diamond particles comprises an interstitial silicon atom and two adjacent vacancies in the diamond lattice. At low temperatures, the energy levels of the silicon vacancy color center comprise a split ground state and a split excited state. The distance between the two split energy levels of the ground state is about 50 GHz, and the distance between the two split energy levels of the excited state is about 250 GHz. There are four allowed optical transitions.

A second aspect of the present invention provides a preparation method for a nanodiamond particles based physical unclonable functional material. The preparation method comprises the steps of:
(1) treating the nanodiamond particles with salt-assisted air oxidation;
(2) making a seed crystal suspension with the treated nanodiamond particles;
(3) applying the seed crystal suspension to the surface of a monocrystalline silicon substrate to form seed crystals, and applying chemical vapor deposition to grow nanodiamond particles with silicon vacancy color centers.

According to a preparation method provided by the present invention, the salt-assisted air oxidation treatment comprises mixing nanodiamond particles with a soluble salt and heating in the air at 200-900° C. for 1 minute to 24 hours. Preferably, the soluble salt is Sodium chloride.

According to a preparation method provided by the present invention, the seed crystal suspension comprises one or a combination of dimethyl sulfoxide, absolute ethanol, acetone, or water as a dispersion solvent.

According to a preparation method provided by the present invention, the step (3) comprises treating the monocrystalline silicon substrate with hydrogen plasma before the growth of nanodiamond particles. Preferably, the treatment conditions are: the power being 100-2000 W., the chamber pressure being 0.1˜100 torr, the hydrogen (H₂) gas flow being 5˜1000 sccm, and the processing time being 1˜60 minutes.

According to a preparation method provided by the present invention, the growth conditions of the chemical vapor deposition method in step (3) comprises: spin coating the seed crystal suspension on a pretreated silicon substrate surface (spin coating parameter: 100˜ 5000 r/min, add 1 to 10 drops within 5 to 60 seconds, then increase the rotation speed to 1000 to 10000 r/min, spin coat for 10 to 300 seconds and spin dry), and repeat 1 to 30 times. Then, the silicon substrate spin-coated with diamond seeds are subjected into a chemical vapor deposition equipment to deposit and grow diamond particles. The microwave power of the equipment is 500˜5000 W, the chamber pressure is 0.1˜100 torr, the growth temperature is 400˜1000° C., and the hydrogen gas flow rate is 100 to 1000 sccm, the flow rate of methane (CH₄) gas is 1 to 100 sccm, and the growth time is 10 to 120 minutes.

According to a preparation method provided by the present invention, the preparation method further comprises a step (4) of heating the generated diamond particles in air to increase the photoluminescence intensity of the silicon vacancy color center. The inventor of the present invention remarkably invented in experiment that the photoluminescence intensity of the silicon vacancy color center can be modulated by oxidizing the generated nanodiamond particles in the air for different periods of time. For example, experimentally results showed that during the cumulative heating at 600° C. in air for 0, 15, 30, 45 and 60 minutes, the photoluminescence intensity of the silicon vacancy color center first increased and then decreased.

The heating temperature in the step (4) is 400-800° C., and preferably 550-650° C. The heating time is 1 minute to 24 hours and preferably 10 minutes to 4 hours, and more preferably 30 to 90 minutes.

A third aspect of the present invention provides an application of nanodiamond particles with silicon vacancy color centers for use as physical unclonable functional materials, wherein the physical unclonable functional materials comprise: a monocrystalline silicon substrate and nanodiamond particles with silicon vacancy color centers grown in situ thereon.

In a preferred embodiment of the present invention, the nanodiamond particles with silicon vacancy color centers are grown on the monocrystalline silicon substrate by a chemical vapor deposition method. Preferably, in the chemical vapor deposition method, nanodiamond particles treated with salt-assisted air oxidization are used as seed crystals.

A fourth aspect of the present invention provides a physical unclonable functional label, which comprises a nanodiamond particles based physical unclonable functional material of an embodiment of the present invention or a nanodiamond particles based physical unclonable functional material prepared according to the preparation method of an embodiment of the present invention.

The physical unclonable functional material and its preparation method of an embodiment of the present invention have the following characteristics and beneficial effects:

(1) The preparation or formation process of nanodiamond particles on a silicon substrate is a stochastic (non-deterministic) or random formation process, which is one of the essential requirements for manufacturing PUF labels. The developed diamond PUF shows excellent performance in terms of capacity, diversity, safety, manufacturability, robustness and compatibility. The fabricated diamond-based anti-counterfeiting labels showed superior stability under extreme conditions, including harsh chemical environments, high temperatures, mechanical abrasion, and UV light exposure. The multi-modal, dynamic encoding capabilities and excellent robustness of diamond PUFs show great potential in unbreakable anti-counterfeiting applications.

(2) Physical unclonable functions are produced in a chemical vapor deposition process. Therefore, the physical unclonable functional material of an embodiment of the present invention can be seamlessly integrated into modern microelectromechanical systems (MEMS) or nanoelectromechanical systems (NEMS), and mass-produced on semiconductor chips, silicon substrates or silicon wafers. Additionally, the complexity and high cost of vapor deposition equipment will also make it more difficult for replicas to appear on the market.

(3) Flexible adjustability of CVD growth parameters (such as gas composition and flow rate, microwave power, pressure, growth time and temperature, diamond seeds and substrates) and high productivity of silicon wafers can make it possible to mass produce large-scale commercial customized diamond-PUF labels. In addition, the in-situ heterogeneous CVD growth method of nanodiamond particles on the substrate (rather than direct drop coating/spin coating of pre-synthesized particles on the substrate to produce PUF labels) greatly enhances the bonding of the nanodiamond particles with the silicon substrate. This process further ensures that the diamond-PUF label of the present invention as a whole device has excellent stability.

(4) The high-quality silicon vacancy nanodiamond particles of the present invention have photoluminescence modulation properties (via air oxidation), which provide further security for PUF labels.

(5) The present invention makes use of the photoluminescence intensity, scattering spectrum, morphological characteristics and spatial position relationship of diamond particles as the fingerprint information of the diamond PUF anti-counterfeiting label. Due to the extreme heat resistance, mechanical, chemical and light stability of diamond material. The highly robust label of the present invention can satisfy the requirements of many practical applications in various environments. The present invention has huge applications. The present invention has real commercial value in the anti-counterfeiting market for electronic components, medical packaging, vehicles, luxury goods, etc.

### BRIEF DESCRIPTION OF THE DRAWINGS

The embodiments of the present invention are described in detail with reference to the accompanying drawings below, wherein:

FIG. 1 shows the silicon vacancy structure and its energy level of a nanodiamond particles based physical unclonable functional material of an embodiment of the present invention;

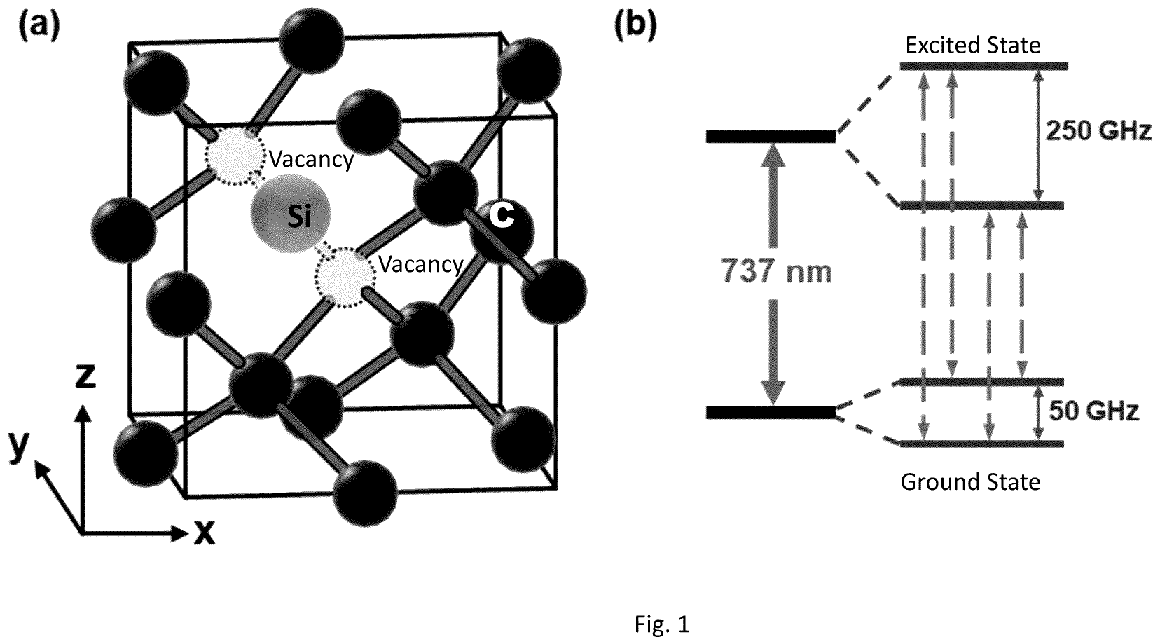

FIG. 2 is a schematic diagram of the appearance and structure of nanodiamond particles prepared on a silicon substrate in Example 1;

FIG. 3 is a chart showing the fluorescence emission spectrum of nanodiamond particles prepared in Example 1;

FIG. 4 is an image from a scanning transmission electron microscope (STEM) and a diagram of the corresponding electron energy loss spectrum (EELS) element of the nanodiamond particles in Example 1;

FIG. 5 is an image from a scanning electron microscope (SEM) of the nanodiamond particles in Example 1 and an image from a dark field microscope of the same area;

FIG. 6 shows specific SEM images and corresponding scattering spectra of five nanoparticles randomly selected from the area in FIG. 5;

FIG. 7 shows diagrams of the encoding results of the scattering signal from the nanodiamond particles produced in Example 1;

FIG. 8 shows diagrams of the encoding results of the silicon vacancy photoluminescence intensity from the nanodiamond particles prepared in Example 3;

FIG. 9 is an image from a confocal fluorescence microscope of a particular 20 μm×20 μm area of the nanodiamond particles prepared in Example 3 during oxidation in air at 600° C. in 15 minutes intervals and repeated four times (a total of 60 minutes).

FIG. 10 is an SEM image of the nanodiamond particles prepared in Example 3 after being oxidized in air at 600° C. for 15, 30, 45 and 60 minutes;

FIG. 11 is the SEM image result of the stability analysis of the nanodiamond particles in Example 3;

FIG. 12 is a confocal fluorescence microscope image of the stability analysis of the nanodiamond particles in Example 3;

FIG. 13 is an SEM image of the products with different nanodiamond particles coverage prepared in Examples 2-5;

FIG. 14 shows the encoding method of the light scattered signals from the diamond particles;

FIG. 15 shows the reading process of a diamond-PUF tag using 532 nm green laser;

FIG. 16 shows diagrams showing the impact of SiV PL-based encoding results on the same diamond-PUF label under different measurement conditions (ambient light, exposure time and laser power);

FIG. 17 shows diagrams showing the modulation process of SiV PL in nanodiamond particles;

FIG. 18 shows the stability test results of diamond-PUF anti-counterfeiting labels;

FIG. 19 is a schematic diagram showing a diamond-PUF-based authentication protocol;

FIG. 20 is a schematic diagram showing an information encryption and decryption scheme based on diamond-PUF.

### BEST METHOD TO IMPLEMENT PRESENT INVENTION

The present invention will be further described below with reference to the examples. The examples are only illustrative and are in no way meant to limit the scope of the present invention.

In order to facilitate understanding, some technical terms of the present invention are defined or explained below.

### Evenness

Evenness can be calculated using the following formula:

$$Evenness = \frac{1}{n} {\sum }_{i = 1}^{n} {R}_{i}$$

wherein, Rᵢ is the corresponding i^{th} bit in an n bits encryption key.

### Similarity or Similarity Index

The Similarity Index (I) is applied to measure the similarity of different PUFs, and can be calculated using the following formula:

$$I = \frac{A}{B} \times 100 \%$$

wherein, A is the count of the same pixel in two PUFs, and B is the total count of pixels.

### Hamming Distance

The Hamming distance between two encryption keys is the minimum number of substitutions required to transform one encryption key into the other. Hamming distance is used to quantify the uniqueness of a PUF. It represents the ability to distinguish one PUF from other PUFs. In addition, Hamming distance can be used to quantify the reliability of the same PUF label, or to check whether it has the ability to generate consistent keys under multiple measurements. Hamming distance can be used to evaluate the uniqueness and reliability of PUF. The specific calculation formula is as follows:

$$Uniqueness = \frac{2}{N ( N - 1 )} {\sum }_{i = 1}^{N - 1} {\sum }_{j = i + 1}^{N} \frac{H D ( {R}_{i} , {R}_{j} )}{n}$$

wherein Rᵢ and Rⱼ are the i^{th} and j^{th} n digits PUF encryption key, and N is the total number of PUF.

$$Reliability = \frac{1}{N} {\sum }_{i = 1}^{N} \frac{H D ( {R}_{0} , {R}_{i} )}{n}$$

wherein R₀ is the original n digits PUF encryption key, Rᵢ is n digits PUF encryption key generated from the i^{th} measurement of N total N measurements.

### Example 1

### (1) Salt-Assisted Air Oxidation

0.5 g of nanodiamond (HPHT, PolyColor, China) with an average particle size of 50 nm is mixed with 2.5 g of sodium chloride (NaCl, 99.5%, Sigma-Aldrich) and heated at 500° C. in air for 1 hour.

### (2) Preparation of Chemical Vapor Deposition Seed Crystal Suspension

The samples obtained from (1) are dispersed in deionized water and subject to ultrasonic treatment for 1 hour. Then, the nanodiamond particles are purified with deionized water three times using centrifugation. The purified nanodiamond is redispersed in deionized water and subjected to ultrasonic treatment for 2 hours to obtain a well-dispersed nanodiamond seed crystal suspension for chemical vapor deposition growth diamond, in which the concentration of nanodiamond is 1 mg/mL.

### (3) Chemical Vapor Deposition Process to Prepare Nanodiamond Particles on a Silicon Substrate or Silicon Wafer.

First, the silicon substrate (2 inches) is treated with hydrogen plasma through a microwave plasma-assisted chemical vapor deposition (MPCVD) system (Seki 6350) at a power of 1300 W, a chamber pressure of 35 torr, and a hydrogen gas flow of 300 sccm for 10 minutes. Then, spin-coat the prepared chemical vapor deposition nanodiamond seed suspension on the surface of the standard monocrystalline silicon substrate (spin coating parameter: 500r/min, add 3 drops of 20 uL seed suspension within 15 s, and then increase the rotation speed to 4500 r/min, spin coating for 110 s and spin dry). Repeat this process 5 times. The spin-coated diamond seed crystals silicon substrate is then put into the MPCVD system (Seki6350) to deposit and grow nanodiamond particles. The microwave power of the equipment is set to 3400 W, the chamber pressure is 85 torr, the growth temperature is 920° C., the hydrogen gas flow is 485 sccm, and the methane (CH₄) gas flow rate is 15 sccm and the growth time is 80 minutes.

### Example 2

The nanodiamond particles are prepared on the silicon substrate in the same method as described in Example 1, except that in step (3), the spin coating of the diamond seed crystal suspension on the surface of the standard monocrystalline silicon substrate is performed only 1 time.

### Example 3

The nanodiamond particles are prepared on the silicon substrate with the same method as in Example 1, except that in step (3), the spin coating of the diamond seed crystal suspension on the surface of the standard monocrystalline silicon substrate is repeated 10 times.

### Example 4

The nanodiamond particles are prepared on the silicon substrate with the same method as in Example 1, except that in step (3), the spin coating of the diamond seed crystal suspension on the surface of the standard monocrystalline silicon substrate is repeated 20 times.

### Example 5

The nanodiamond particles are prepared on the silicon substrate with the same method as in Example 1, except that in step (3), the spin coating of the diamond seed crystal suspension on the surface of the standard monocrystalline silicon substrate is repeated 25 times.

### Example 6

### Method of Using Scattered Signals of the Nanodiamond Particles for Representative Encoding

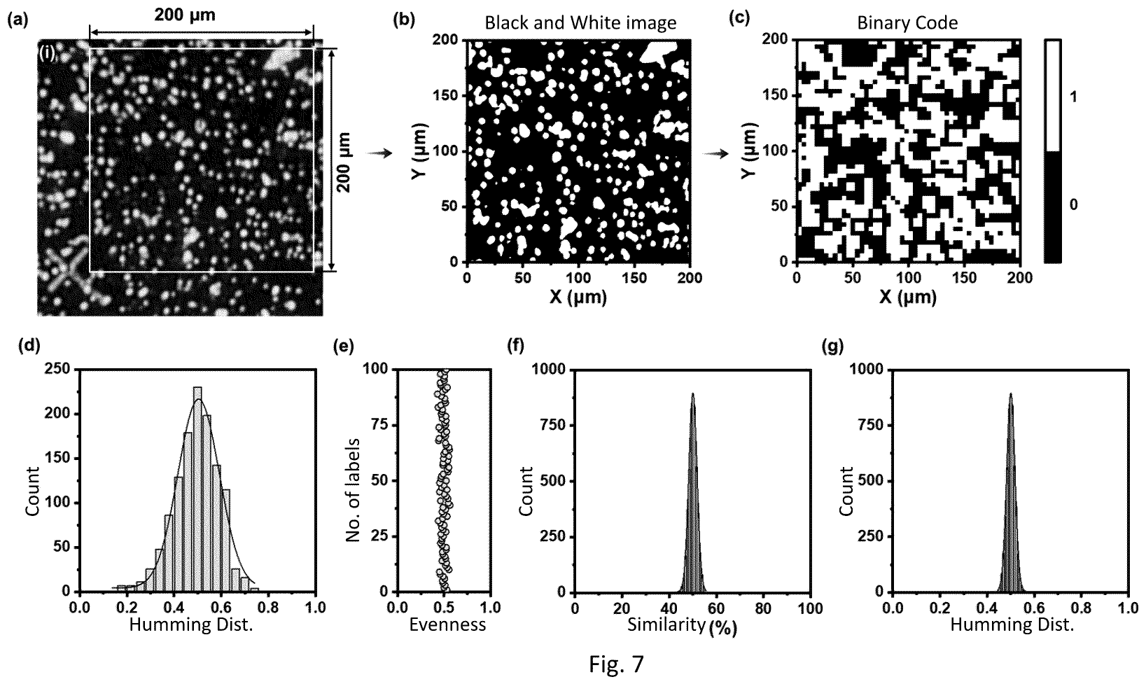

Use an optical microscope to take an image of the nanodiamond particles prepared in Example 1 under bright field; randomly select an image region of 200 μm×200 μm; the image is then converted into a black-and-white image using image processing software (such as Photoshop). The corresponding black-and-white image is then encoded into a 50-pixel×50-pixel two-dimensional binary code matrix based on the principle of black (0) and white (1). The result is shown in FIG. 7.

### Example 7

Method of Using Photoluminescence Intensity from Silicon Vacancies in Nanodiamond Particles for Representative Encoding

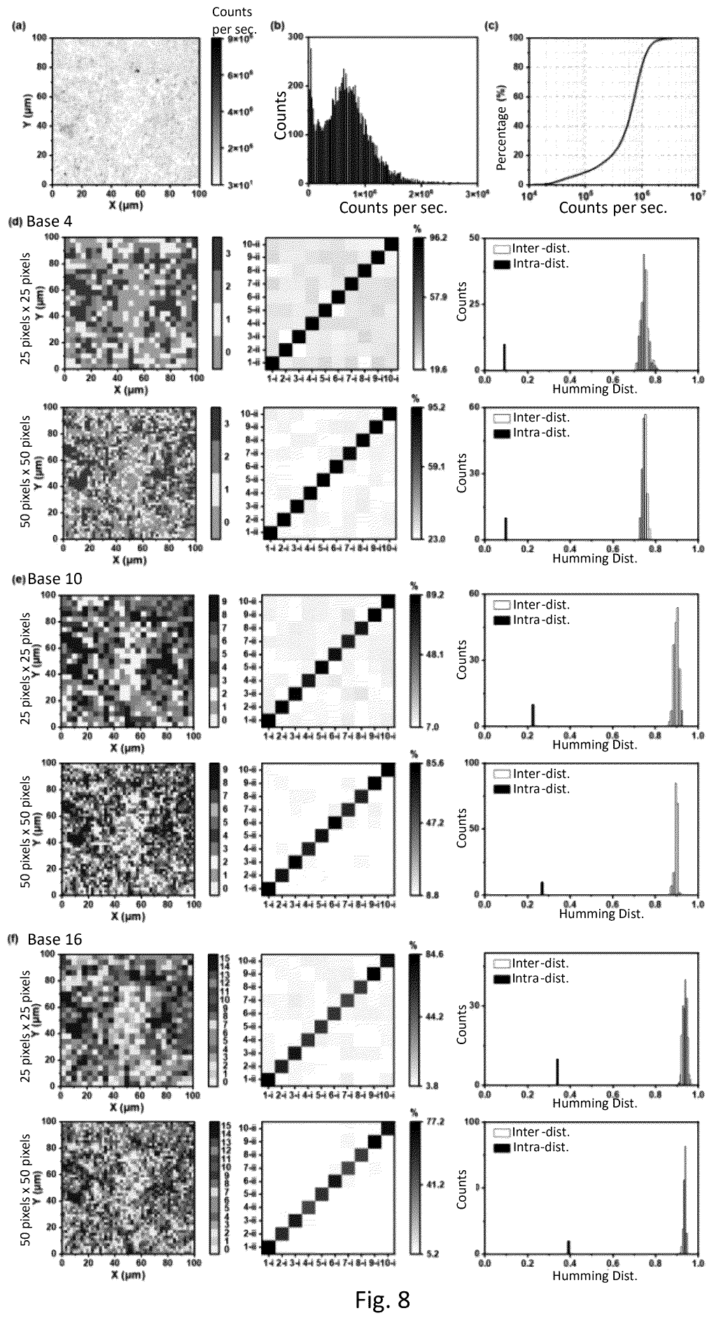

Use a confocal fluorescence microscope to take a photoluminescence image of the nanodiamond particles prepared in Example 3 with an image region of 100 μm×100 μm area (100 pixels×100 pixels); combine the photoluminescence intensity data (counts per second interval) of every 2 pixels×2 pixels (or 4 pixels×4 pixels) into 1 single pixel photoluminescence intensity data to form a new 50 pixels×50 pixels (or 25 pixels×25 pixels) image; divide the photoluminescence intensity data (counts per second interval) of each pixel in the new image into 4 groups (base 4 encoding), 10 groups (base 10 encoding) or 16 groups (base 16 encoding) according to the order of intensity. hexadecimal encoding). The results are shown in FIG. 8.

### Example 8

Photoluminescence Modulation Method Chemical Vapor Deposition Grown Nanodiamond Particles with Air Oxidation

The nanodiamond particles prepared in Example 3 are heated at 600° C. for 15 minutes in the air and repeated four times to achieve photoluminescence intensity modulation of the silicon vacancy color center in the nanodiamond particles.

### Method for Characterizing the Appearance and Performance

The morphology or appearance of nanodiamond particles can be analyzed using a scanning electron microscope (SEM, Hitachi S-4800, Japan). The composition elements can be analyzed using electron energy loss spectroscopy (EELS) equipped with a scanning transmission electron microscope (STEM, JEM-2100F). The crystallinity can be analyzed using X-ray diffraction (XRD, D8 Advance, Bruker). The samples are optically characterized using a dark-field microscope equipped with a spectrometer built in-house in the laboratory. The samples are optically characterized using a confocal fluorescence microscope equipped with a spectrometer built in the laboratory.

### Method for Measuring the Stability of Nanodiamond Particles

Chemical stability: The prepared nanodiamond particles are soaked in supersaturated sodium chloride (NaCl), 1 mol/L of hydrochloric acid (HCl) and 1 mol/L of sodium hydroxide (NaOH) solutions for 48 hours, and then rinsed with clean water.

Thermal stability: The prepared nanodiamond particles are heated from room temperature to 400° C. in the air and kept at 400° C. for 48 hours.

Mechanical stability: The prepared nanodiamond particles are mixed with sand, physically rubbed for 30 minutes, and then cleaned with water under ultrasound (1 hour).

Light stability: The prepared nanodiamond particles are exposed to ultraviolet light (365 nm) for 2 hours.

After each of the above stabilization treatments, the functionality of the diamond particles is characterized.

### Result and Analysis

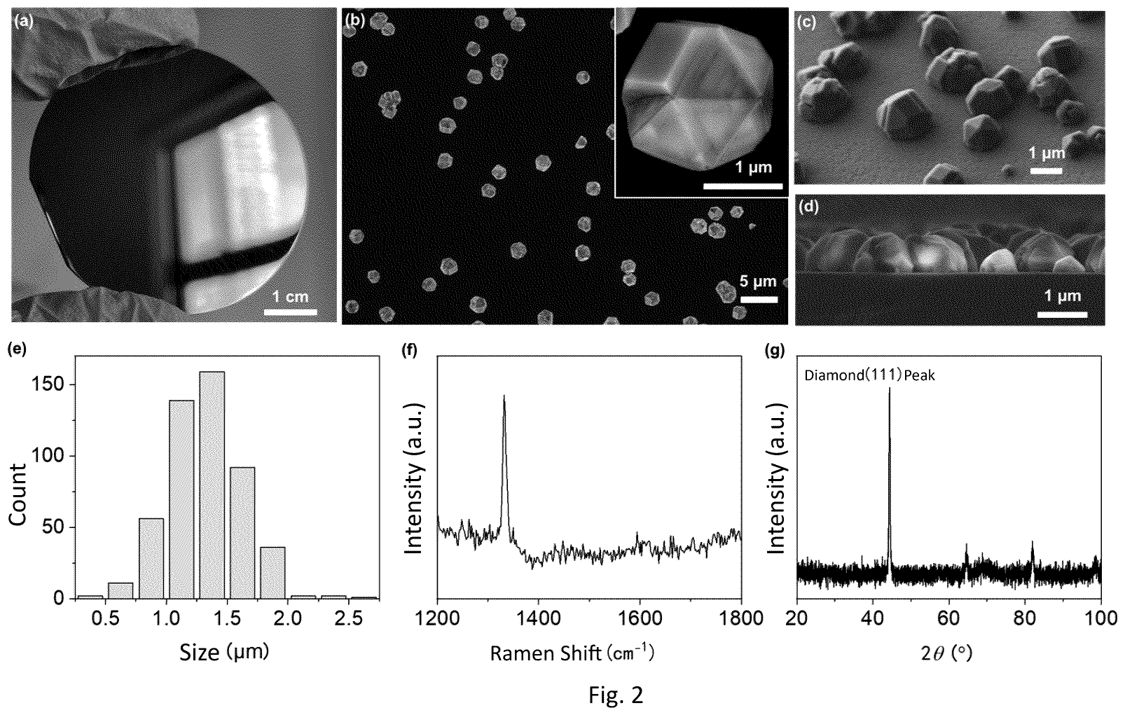

(1) FIG. 2 shows the morphological characterization results of nanodiamond particles prepared on silicon wafers in Example 1, specifically including: (a) a photo of a silicon substrate or silicon wafer whose surface is covered with diamond particles; (b) the corresponding SEM image, (c) SEM image observed at 45°, (d) cross-section SEM image, (e) size distribution of grown diamond particles calculated based on SEM image (average size is about 1.32 μm), (f) Raman spectrum diagram, and (g) X-ray diffraction spectrum.

Raman spectrum and X-ray diffraction spectrum results demonstrate the pure crystalline nature of the grown nanodiamond particles. At the same time, the etching of the silicon substrate during the chemical vapor deposition process will produce a large number of doped silicon atoms, which can enter the diamond lattice to form silicon vacancy color centers. This demonstrates better fluorescence properties than the silicon vacancy color centers produced by ion implantation.

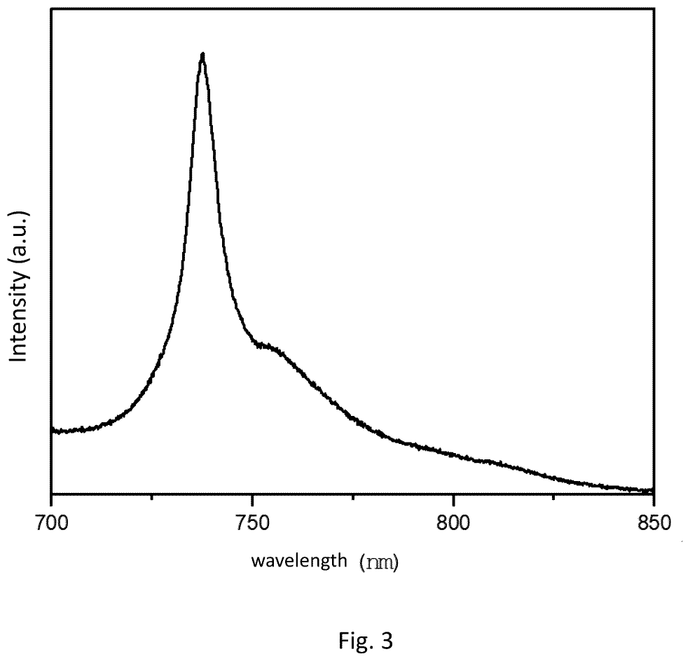

2) Room temperature photoluminescence characteristics of nanodiamond particles grown by chemical vapor deposition method. The ideal fluorescent anti-counterfeiting label requires materials with strong fluorescence (photoluminescence) intensity to ensure high fluorescence brightness. FIG. 3 shows that the nanodiamond particles prepared in Example 1 exhibit a narrow fluorescence emission peak at approximately 737 nm (excitation light is 532 nm).

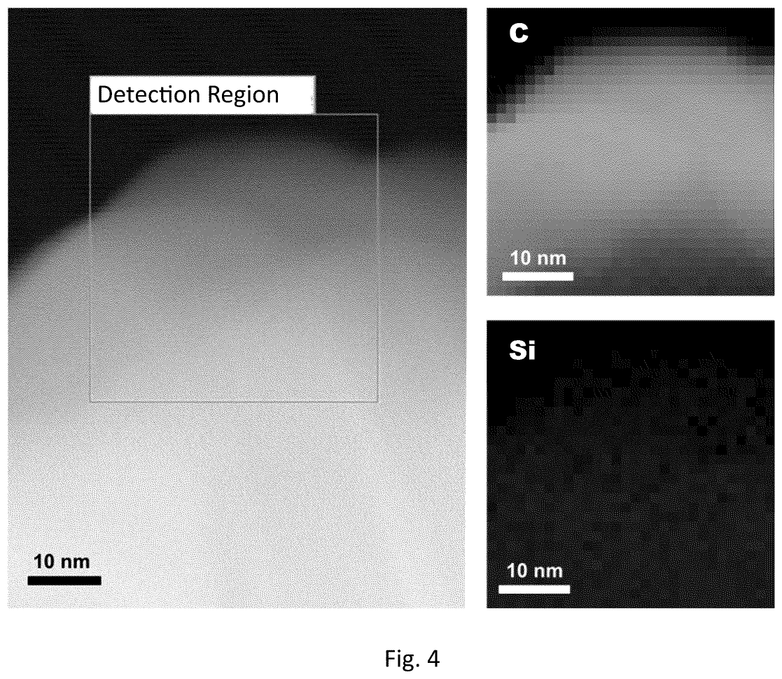

FIG. 4 shows (a) the STEM image and (b) the corresponding EELS element distribution image of the nanodiamond particles in Example 1, indicating that a large number of doped silicon atoms are uniformly distributed within the nanodiamond particles.

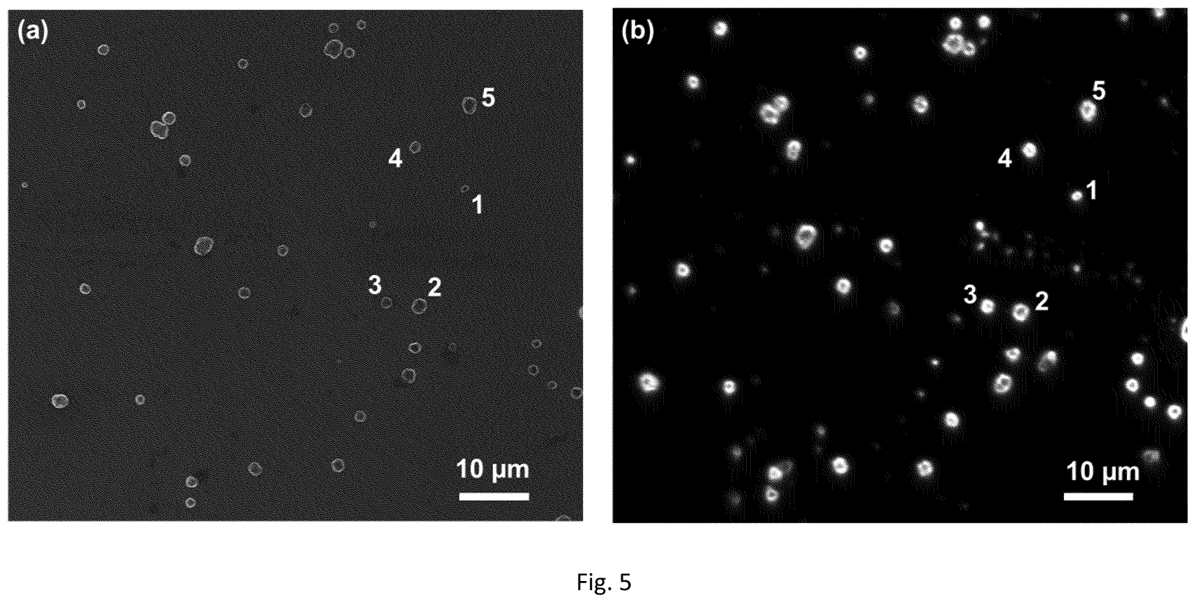

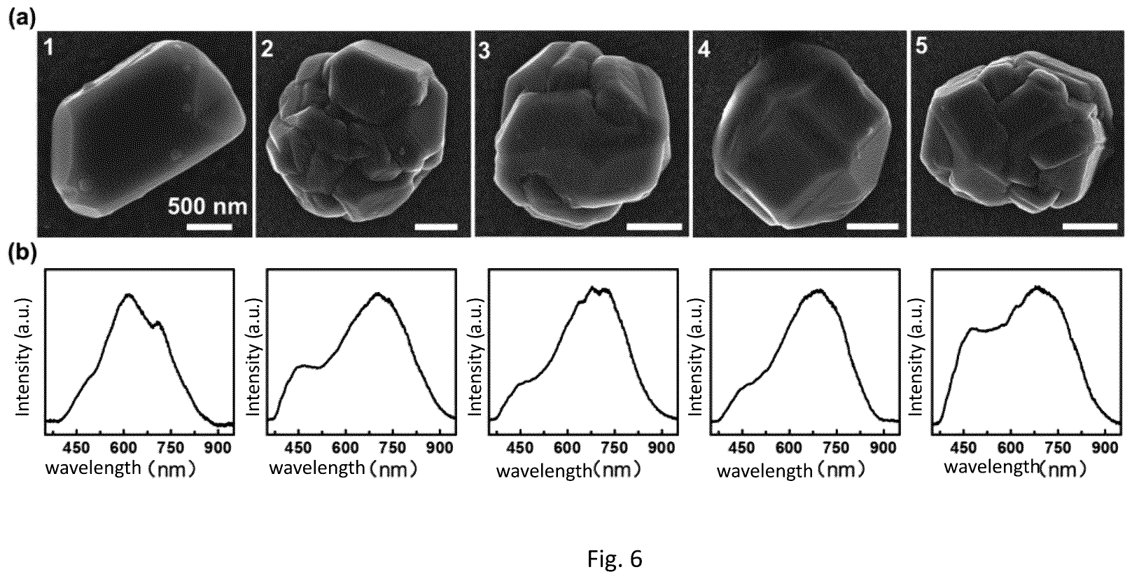

(3) FIG. 5 shows (a) a SEM image and (b) a dark field microscope image of the same region of nanodiamond particles in Example 1 wherein five marked particles 1, 2, 3, 4 and 5 are randomly selected for detailed characterization. FIG. 5 shows that nanodiamond particles are randomly distributed with bright scattering spots. FIG. 6 shows (a) the specific morphology and (b) the corresponding scattering spectra of five randomly selected particles 1, 2, 3, 4 and 5 from the region in FIG. 4. The scattering peaks are mainly distributed between 450 and 800 nm, and each spectrum has its unique peak position, intensity and spectral line width. At the same time, it can be seen from the SEM image that the shapes of the particles are different. In other words, the shape and scattered spectrum of each nanodiamond particle appear to be unique. Therefore, the scattering spectra of nanodiamond particles as well as their morphological characteristics and spatial position relationships can be used as fingerprint information of diamond PUF. This is one of the most important factors to consider for practical applications of detecting or reading optical diamond labels easily, quickly and cheaply. By using a portable reading device (e.g., a smartphone camera), the scattering point pattern and scattering intensity of the nanodiamond particle PUF label can be obtained simultaneously from a single image. This allows the reading of the optical labels flexibly.

(4) FIG. 7 shows a representative encoding process using the scattering signal of nanodiamond particles. First, use an optical microscope to take an image (a) of the nanodiamond particles prepared in Example 1 under bright field, and randomly select a region of 200 μm×200 μm; use image processing software (such as Photoshop) to convert the region image into (b) a black and white or binary color image; encode the corresponding black and white image into a two-dimensional binary encoding matrix (c) of 50 pixels×50 pixels according to the principle of black (0) and white (1); verify that the two-dimensional binary coded matrix using Hamming distance (d) has good randomness; randomly test the encoding results of 100 other regions in order to show that the nanodiamond PUF label has good (e) uniformity; verify different labels to have low (f) similarity index and good (g) Hamming distance between labels.

(5) FIG. 8 shows a representative encoding process of photoluminescence intensity of silicon vacancies using nanodiamond particles. First, use a confocal fluorescence microscope to obtain a photoluminescence image (a) of the nanodiamond particles prepared in Example 3 with a region of 100 μm×100 μm (100 pixels×100 pixels). From (b) distribution diagram and (c) accumulation curve of the photoluminescence intensity of the corresponding measurement area (counts per second interval), it can be observed that the silicon vacancy photoluminescence intensity of the prepared diamond particles has a very large distribution space, which is very suitable for use in the multi-bases encoding process.

Specifically, the photoluminescence intensity data (counts per second) of every 2 pixels×2 pixels (or 4 pixels×4 pixels) of the photoluminescence image measured in (a) are combined into the photoluminescence intensity data of 1 pixel point (counts per second) to form a new 50 pixels×50 pixels (or 25 pixels×25 pixels) image. Then the photoluminescence intensity data (counts per second) of each pixel in the newly composed image is divided into 4 groups according to the order of intensity and perform (d) base 4 encoding, and divided into 10 groups for (e) base 10 encoding, or divided into 16 groups for (f) base 16 encoding. In (d), (e), and (f) of FIG. 8, the upper part is the 25 pixels×25 pixels encoding result, the lower part is the 25 pixels×25 pixels encoding result, the diagram on the left is the specific encoding matrix, and the diagram in the middle is the detection results of the similarity index (10 labels, each measurement is performed twice), the diagram on right shows the inter- and intra-class Hamming distances for 10 labels. From the above results, it is observed that the photoluminescence intensity of silicon vacancies in diamond particles makes it possible to manufacture multi-dimensional PUF labels with large encoding capacity.

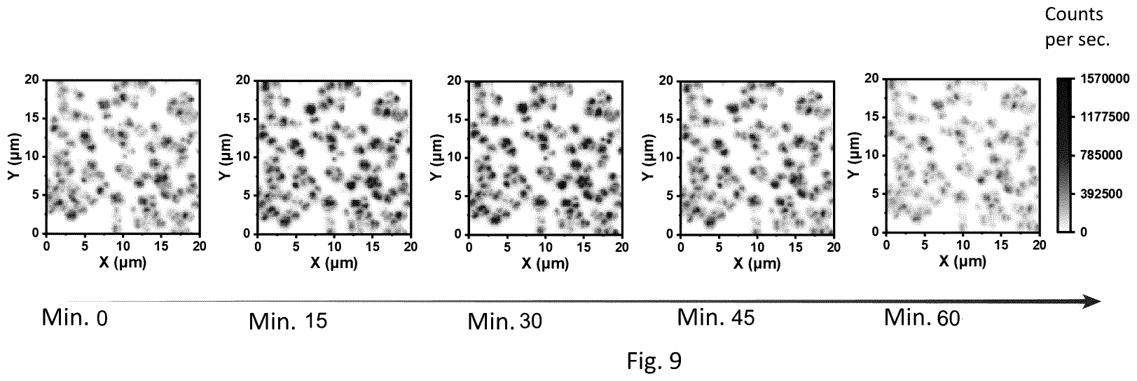

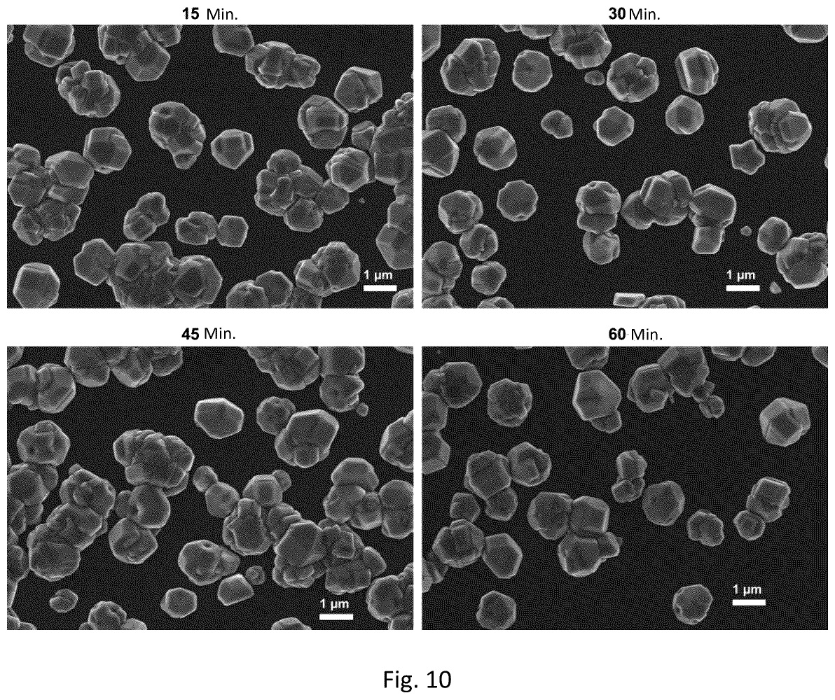

(6) FIG. 9 shows the photoluminescence image of an arbitrary region of 20 μm×20 μm taken each time when the nanodiamond particles prepared in Example 3 are oxidized in air at 600° C. for 15 minutes and repeated 4 times (a total of 60 minutes). It is observed that the photoluminescence intensity of silicon vacancy color centers in nanodiamond particles changes in correspondence with oxidation. Also, it is observed that the air-oxidized nanodiamond particles show no obvious morphological variation (FIG. 10). Therefore, this silicon vacancy color center photoluminescence modulation property provides the diamond labels with an “internal” security key.

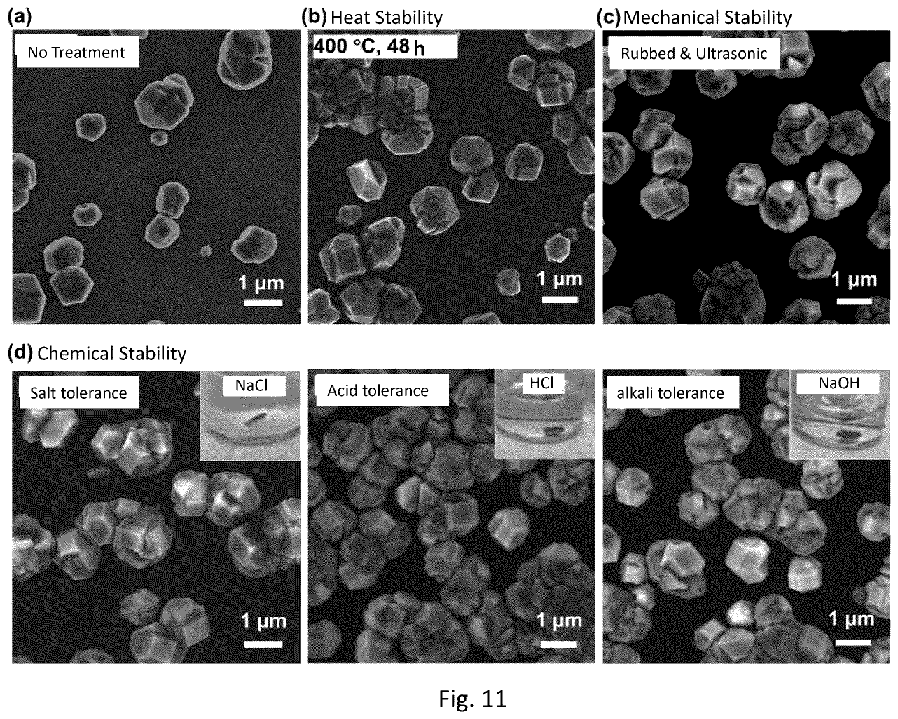

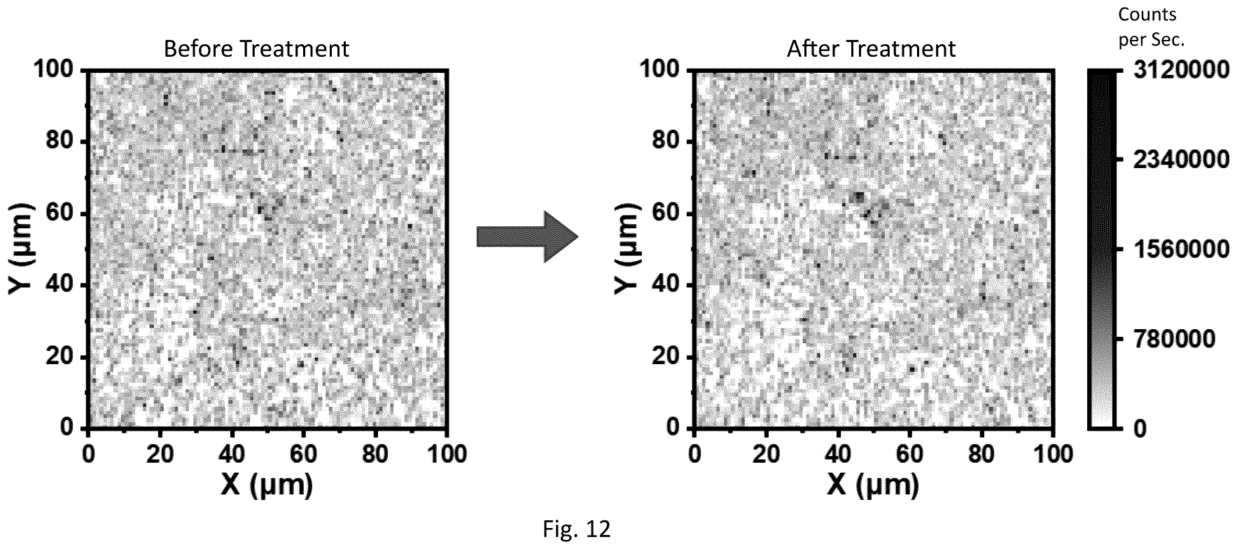

(7) The stability analysis results are shown in FIG. 11, in which: (a) SEM image of untreated original nanodiamond particles; (b) Thermal stability: SEM image of nanodiamond particles after heating at 400° C. for 48 hours; (c) Mechanical stability: SEM image of nanodiamond particles after rubbing with sand and washing; (d) Chemical stability: SEM image of nanodiamond particles soaked in supersaturated sodium chloride (NaCl), 1 mol/L of hydrochloric acid (HCl) and 1 mol/L of sodium hydroxide for 48 hours. In addition, the confocal fluorescence images of nanodiamond particles before and after being treated with salt (NaCl), acid (HCl), alkali (NaOH), high temperature (400° C.), mechanical force and ultraviolet light (365 nm) are also obtained (FIG. 12). The results show that this series of treatments does not cause any damage to the photoluminescence properties of nanodiamond particles or encoding capacity. It can be seen that the diamond PUF of the present invention has excellent robustness to salt (NaCl), acid (HCl), alkali (NaOH), high temperature (400° C.), mechanical force and ultraviolet light.

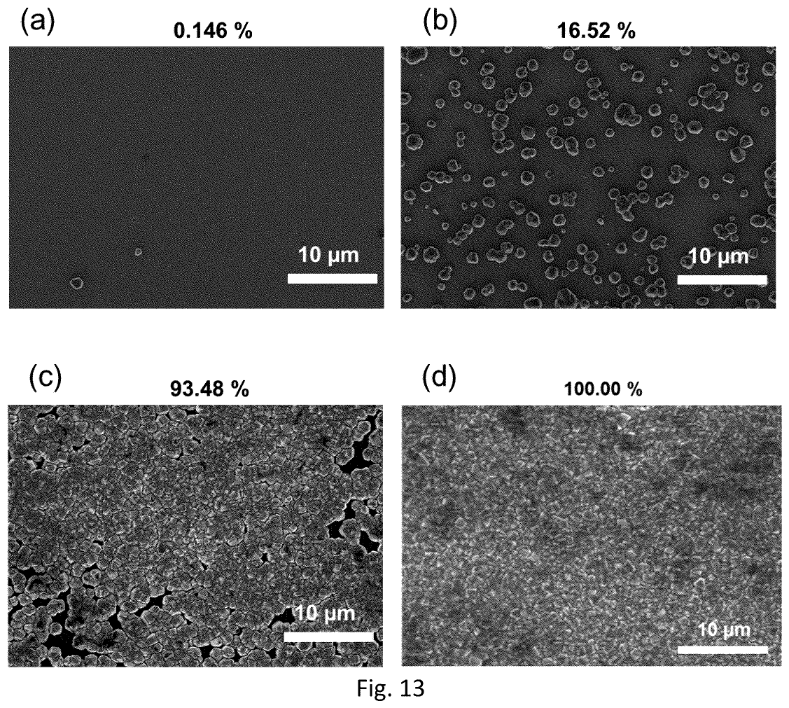

(8) In Examples 2-5, by adjusting the growth parameters (the number of repetitions of spin coating of the diamond seed crystal suspension on the surface of a standard monocrystalline silicon substrate), the grown diamond particles cover 0.146% to 100.00% of the silicon wafer. (SEM images of Examples 2-5 are shown in (a)-(d) of FIG. 13 in sequence). This further proves that there is huge space for adjusting the encoding capability of the diamond PUF label of the present invention.

### Static Encoding Based on Light Scattering Signals of Nanodiamond Particles

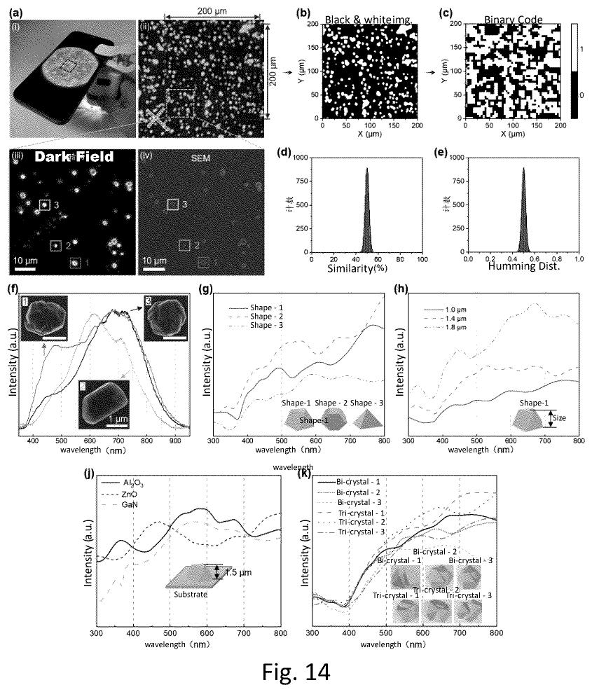

In actual anti-counterfeiting applications, diamond-PUF labels have the ability to be detected and read quickly, cheaply and conveniently. FIG. 14 shows an encoding method based on the scattering light signals of nanodiamond particles, wherein: (a) includes (i) an authentication device composed of a portable microscope and a smartphone; (ii) the optical image of a nanodiamond-PUF label taken by the portable microscope; (iii) a dark field microscope image of the dotted line area of FIG. 14 (ii); (iv) SEM image of the dotted line area in FIG. 14 (ii); (b) is a black and white image converted from a 200 μm×200 μm of the dotted line area in FIG. 14 (a-ii); (c) is the corresponding binary encoding matrix based on the dark (0) and light (1) levels of each pixel in (b), with a resolution of 50 pixels×50 pixels; (d) is the distribution (normalized) result of similarity index and (e) Hamming distance, obtained by analyzing the secret keys generated by 100 labels; (f) is three random nanodiamond particles in the selected area (scattering spectra and corresponding SEM images of particles 1, 2 and 3 in FIG. (a-iii) and (a-iv)); (g) for different shapes (˜1 μm), (h) sizes (shape −1: cuboctahedron), (j) substrates (˜1.5 μm) and (k) crystallinity (twin and triple crystals) from numerical calculation of the scattering spectral results of the nanodiamond particles.

Due to the high refractive index of the diamond material (approximately 2.4), the manufactured diamond-PUF labels can be easily read by portable reading devices. For example, FIG. 14 (a-i) shows an image taken from a portable microscope of a smartphone. This allows the diamond-PUF labels or tags to be easily detected without the need for complex instrumentation. FIG. 14 (a-ii) shows a typical optical image of a diamond-PUF label taken by a portable device. To create general use quantitative metrics for PUF research, optical images will be converted into security keys. For this purpose, the image is binarized and reduced to 50 pixels×50 pixels ((b) and (c) of FIG. 14). In FIG. 14 (c), the white pixels correspond to bright areas that come from the light scattering signal of the nanodiamond particles on the PUF label. Furthermore, the Hamming distance (normalized), measures the minimum number of permutations between different rows within the corresponding binary encoding matrix. The calculation results conform to the normal distribution of the generated security encryption keys. This binary image is then used to generate a security encryption key of 2500 bits in length, consisting of 1 and 0 bits. This process is repeated on 100 samples to generate 100 different security encryption keys. For each of these security encryption keys, the evenness, similarity index (percentage of the same number of pixels between two PUFs, FIG. 14 (d)) and Hamming distance (FIG. 14 (e)) are calculated. The calculated results show that the values of evenness (0.4996), similarity index (49.9978%) and Hamming distance (0.5000) are close to the ideal values (i.e. 0.5, 50% and 0.5), which illustrates that the diamond PUF of the present invention has good evenness, uniqueness and randomness characteristics.

Typically, it is not secure enough when using scattering patterns for advanced security applications because it is easy to replicate using 3D nanoprinting or other assembly techniques. To improve the security of PUF labels, the scattering spectrum of nanodiamond particles can be further exploited. The scattering spectra of nanodiamond particles have been shown to be extremely sensitive to their topologic structures, such as size, shape and crystallinity. Therefore, it is impossible to replicate them exactly with the same spectrum. FIG. 14 (a-iii) and (a-iv) show images of a random area of the diamond-PUF label under dark field microscopy and SEM. The nanodiamond particles are randomly distributed to exhibit bright scattering points, and the detailed shapes and corresponding scattering spectra of some nanoparticles are measured (see FIG. 14 (f)). The scattering peaks are mainly between 450 and 800 nanometers. Each spectrum has its unique peak position, intensity and spectral line width. At the same time, according to the SEM images, no particles have the same shape. In other words, each nanodiamond particle is unique. Therefore, the scattering spectra of nanodiamond particles, together with their shape characteristics and spatial position relationships, can be used as fingerprint information of diamond PUF. In order to explore the possibility of modulating the scattering spectrum, further experiments are carried out with different shapes (FIG. 14 (g)), sizes (FIG. 14 (h)), substrates (FIG. 14 (j)) and crystallinity (FIG. 14 (k)). The scattering spectrum of diamond particles is studied in detail by numerical simulation. The results demonstrate the potential for using diamond scattering spectroscopy as an advanced anti-counterfeiting method. At the same time, due to the high refractive index of diamond, even if it is covered by some protective layer such as SiO₂ or Al₂O₃, it will still be able to provide light scattering signals for reading.

### Static Encoding Based on SiV PL Intensity

In addition to using the light scattering signal of nanodiamond particles as anti-counterfeiting labels, the PL signal of fluorescent color centers (such as SiV color centers) embedded in the diamond lattice can also be used for advanced encoding. The nanodiamond particles that have a large number of doped Si atoms exhibit significant SiV signals. The diamond-PUF label can be encoded by the SiV PL intensity on each pixel of the fluorescence image.

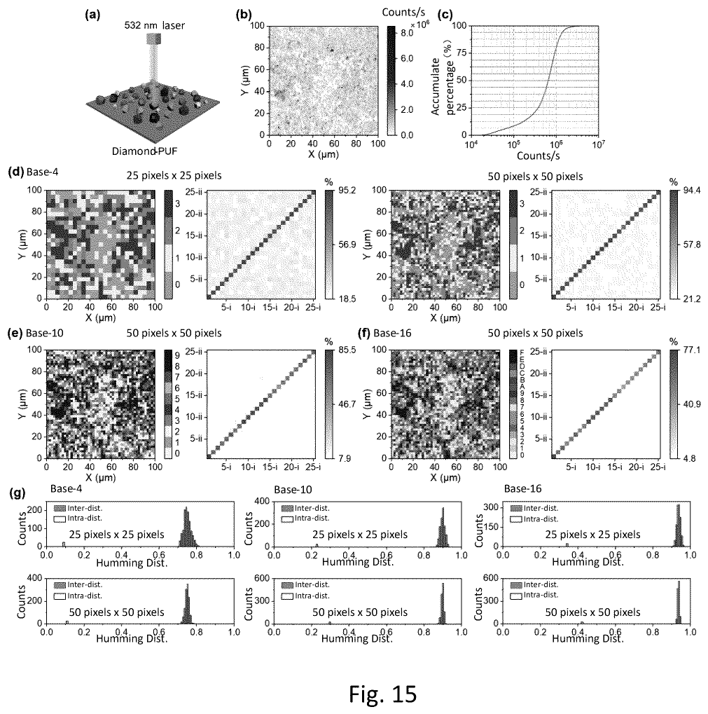

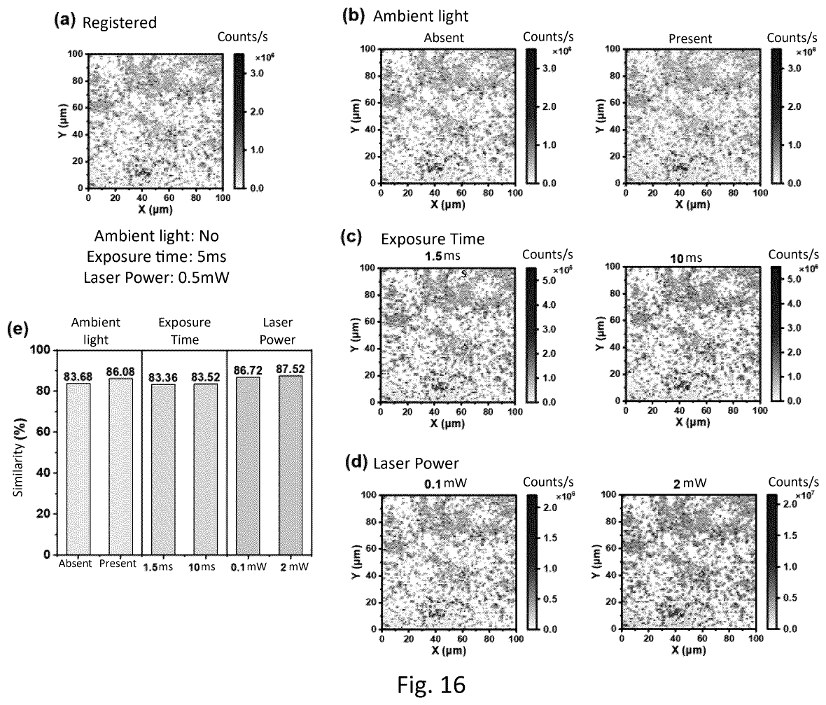

FIG. 15 shows the process for reading diamond-PUF labels using 532 nm green laser, wherein: (a) is a schematic diagram of the process for reading diamond-PUF labels; (b) is a confocal fluorescence image of a 100 μm×100 μm region of a diamond PUF label; (c) shows the cumulative curve of PL intensity (photon count: cps) in the measurement region of (b); (d)-(f) shows the digitized encoding results of the measurement region at a 50 pixels×50 pixels in base 4, base 10 and base 16. Pairwise comparisons of the 25 PUF labels and the PL intensity level of each pixel are provided in base 4, base 10, and base 16 coding. The color bar representing the similarity index is displayed next to the corresponding coding matrix. The x-axis and y-axis represent the first and second measurements of the label, respectively; (g) is an image representing corresponding inter- and intra-hamming distances (normalized) of the security encryption keys generated from 25 labels in base 4, base 10, and base 16. FIG. 16 shows the impact of the SiV PL-based encoding results on the same diamond-PUF label under different measurement conditions (such as ambient light, exposure time and laser power), wherein: (a) is a confocal fluorescence image of the same diamond-PUF label in under standard measurement conditions (no ambient light, 5 ms exposure time, 0.5 mW laser power); (b) is the confocal fluorescence image of the same diamond-PUF label with and without ambient light; (c) is the confocal fluorescence image of the same diamond-PUF label under the exposure time of 1.5 milliseconds and 10 milliseconds; (d) is the confocal fluorescence image of the same diamond-PUF label under the laser power of 0.1 mW and 0.5 mW; (e) is an image showing the analysis results of similarity (%) of the security encryption key in base 4 generated by the same diamond-PUF label under different measurement conditions. During the testing process, other conditions are kept constant except for the conditions being tested, such as when testing the influence of ambient light, the exposure time and laser power are kept constant (5 ms, 0.5 mW).

As shown in FIG. 15(a), a confocal fluorescence image with an area of 100 μm×100 μm of a unique optical fingerprint produced by a diamond-PUF label under a 532 nm laser is provided (see also FIG. 15(b)). This fingerprint cannot be arbitrarily replicated. Due to the diversity of SiV centers in each nanodiamond particle, it is possible to allow each pixel image of PL intensity to achieve higher radix encoding (such as base 4, base 10, and base 16). FIG. 15(c) shows the cumulative curve of the PL intensity (photon count: cps) of the measurement region in image (b) encoded using the principal radix of base 4, base 10, and base 16. All the generated secret encryption keys show even distribution. FIGS. 15(d)-(f) show the result of encoding the measurement region in FIG. 15(b) with base 4, base 10, and base 16 PL encoding. It is easy to observe that the similarities between two readings of the same label are very high, making it easy to distinguish between true and counterfeit labels. FIG. 15(g) shows the distribution of the normalized inter-Hamming distance and intra-Hamming distance (i.e., Hamming distance divided by the key length) of the generated security encryption key in base 4, base 10, and base 16. These results demonstrate that the diamond PUF system of the present invention has the ability to generate different codes. At the same time, when capturing PL images, the impact of measurement conditions (such as ambient light, exposure time, and laser power) does not affect the final security encryption key generated by the PL-based encoding process for the same diamond PUF label (see FIG. 16).

### Dynamic Encoding of SiV PL Intensity Modulation Based on Air Oxidation

Modulation of SiV PL in diamonds has been demonstrated by several methods of treatment, including air oxidation and vacuum annealing. This dynamic and controllable SiV PL system has the potential to be an alternative for developing advanced time-varying encoding methods.

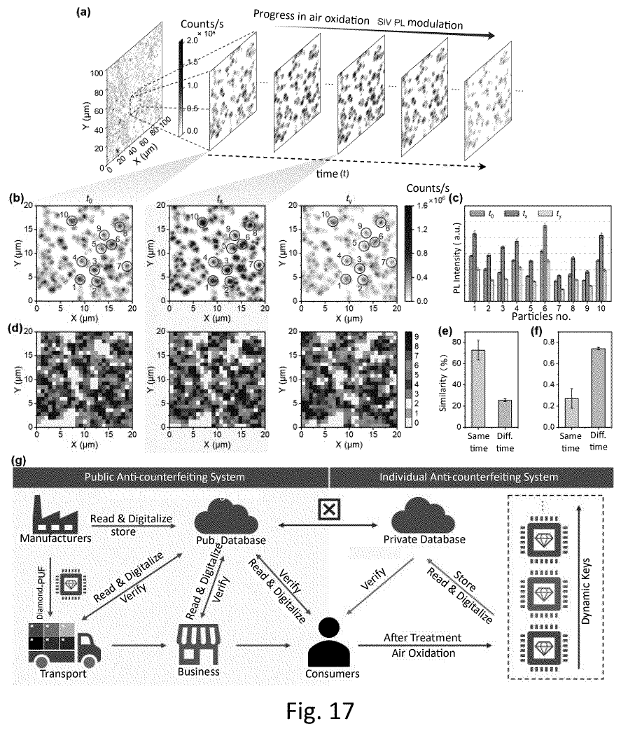

FIG. 17 illustrates a modulation process of SiV PL in diamond particles, wherein: (a) is the confocal fluorescence image of a 100 μm×100 μm region on the diamond PUF label; (b) shows confocal fluorescence images of 20 μm×20 μm dotted line region in (a) at three different times (t₀, tₓ and t_{y}); (c) show 10 random nanodiamond particles circled in (b) at three different times (t₀, tₓ and t_{y}); (d) shows the digitized result of the base 10 encoding of the region shown in (b), based on the PL intensity of each pixel, with a resolution of 25 pixels×25 pixels.

As shown in FIG. 17(a), the SiV PL in the manufactured nanodiamond particles can be modulated by air oxidation (temperature: 600° C., time interval: 15 minutes). Additionally, the nanodiamond particles in the selected region did not show any morphological changes after four rounds of air oxidation treatment. In FIG. 17(b), the 20 μm×20 μm confocal fluorescence images are taken from the dotted line region in FIG. 17(a) at three different times: t₀, tₓ (30 minutes), and t_{y} (60 minutes). The images show that there is an obvious variation in the PL intensity due to the variation in particle counts (see FIG. 17(c)). Therefore, confocal fluorescence images measured at different times (see FIG. 17(b)) can be digitized into different codes (see FIG. 17(d)). There is no strong correlation in these encodings. The analysis results of the similarity index (FIG. 17(e)) and Hamming distance (FIG. 17(f)) of security encryption keys generated in base 10 at the same or different times demonstrate that PL strength modulation can be successfully implemented through the duration of air oxidation. For diamond-PUF labels with the same treatment time period, the average values of the similarity index and Hamming distance are 72.80% and 0.27, with standard deviations of 9.38% and 0.09, respectively. When the diamond PUFs are developed from different treatment times, the mean values of the similarity index and Hamming distance are 25.69% and 0.743, with standard deviations of 1.24% and 0.01. Therefore, air oxidation of a diamond PUF can achieve an overall change in the SiV PL intensity of each of its particles in response to the dynamic construction of a diamond PUF security encryption key. In this case, due to the random modulation of the SiV centers in the diamond, a new security encryption can be generated in every round of air oxidation processes. This non-deterministic, time-varying encoding strategy allows the encoding key of the same PUF tag to be artificially changed when the original tag faces the risk of malicious attacks and replication. This is an ideal feature for designing and manufacturing anti-counterfeiting materials with advanced security.

Furthermore, the accumulation pattern of nanodiamond particles on the substrate can be dynamically controlled by air oxidation. The multigenerational microstructure of nanodiamond particles can also serve as PUF patterns to facilitate time-varying encoding. Therefore, it is possible for end users of the diamond-PUF anti-counterfeiting system (FIG. 17(g)) to use the strategy developed in this invention to build their own database with higher security.

### Stability of Diamond-PUF Anti-Counterfeiting Labels

The above experimental results show that nanodiamond particles on silicon substrates have excellent performance in generating PUF. For practical applications, the chemical, mechanical, thermal and photo-stability of anti-counterfeiting labels are also important. Therefore, the stability of diamond PUF labels on alkali (NaOH), acid (HCl), salt (NaCl), mechanical force, high temperature (400° C.) and UV light are verified.

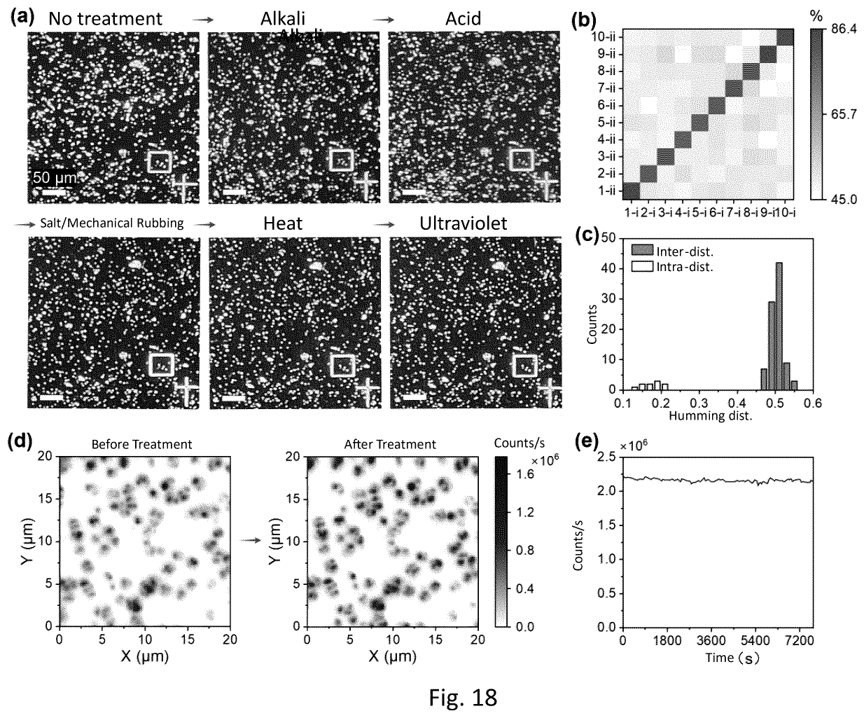

FIG. 18 shows the stability test results of diamond-PUF anti-counterfeiting labels, where: (a) is an optical microscope image of the same area of the diamond-PUF label before and after a series of extreme treatments: (1) soaked in 1 mol/L of NaOH for 24 hours; (2) soak in 1 mol/L of HCl for 24 hours; (3) rubbed with NaCl particles and soaked in supersaturated NaCl for 24 hours, then wash with water in ultrasonic treatment (1 hour); (4) heating at 400° C. for 24 hours; (5) exposure to UV light for 2 hours; (b) is the similarity of the binary security encryption keys generated before and after treatment, the x-axis and y-axis represent the first and second measurements of the label, respectively, and the color bar shows Similarity index; (c) shows the Hamming distance distribution (normalized) of the binary security encryption keys generated by 10 diamond-PUF labels before and after treatment; (d) is a confocal fluorescence image of the same region on a diamond-PUF label before and after a series of extreme treatments; (e) shows the result of the photostability test of SiV color centers in nanodiamond particles (2 hours).

The results indicate that after undergoing a series of extreme treatments, there is no significant change in the optical response and morphology of the nanodiamond particles (see FIG. 18 (a) and (d)). This suggests that nanodiamond particles maintain good stability under various extreme application scenarios. Additionally, the analysis of the similarity of binary security encryption keys generated before and after processing (FIG. 18 (b)) and the Hamming distance (FIG. 18 (c)) shows that the encoding ability of diamond particles remains unaffected by extreme processing. Furthermore, the photostability of the nanodiamond particles is confirmed by exposing the SiV color center nanodiamond particles to a 532 nm laser for 2 hours, resulting in less than 1.19% deviation. These findings demonstrate that the diamond-PUF label of the present invention exhibits excellent chemical, mechanical, thermal, and photostability.

### Diamond Based PUF Authentication Protocol

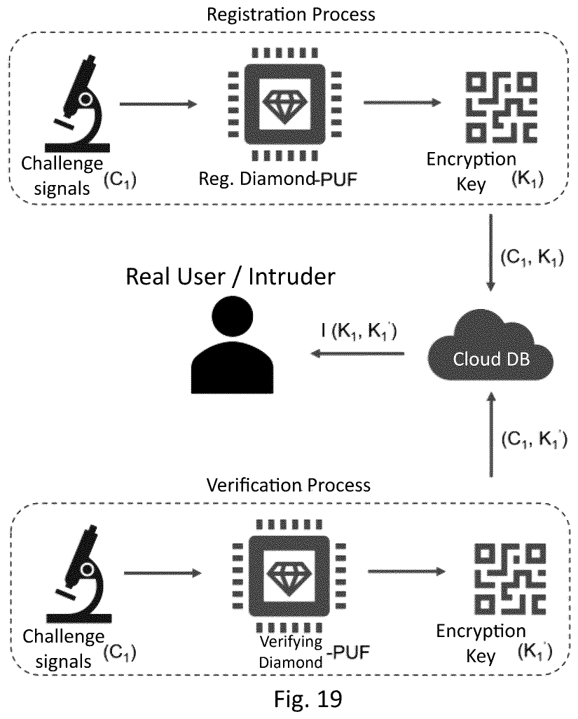

In some embodiments of the invention, authentication may be performed using the materials of the present invention. FIG. 19 shows a schematic diagram of an authentication method, wherein the authentication process is divided into two steps, comprising a registration step and a verification step.

(1) In the registration step, the input challenge signal (C₁) is projected onto the diamond-PUF to generate a related response signal (R₁), and the response signal (R₁) is further converted into an encryption key (K₁). Then, a challenge-response pair registration information generated by C₁ and K₁ is stored in the database or cloud database.

(2) In the verification step, the verifier randomly selects C₁ from the cloud database to challenge a PUF to be authenticated, and obtains a verification code K₁′. The verification code is uploaded to the database or cloud database. Then, the similarity index (I) or Hamming distance between K₁ and K₁′ is calculated. If I_{(K1, K1′)} is larger than the predetermined threshold, the verification is true; otherwise, the verification result is false.

Information Encryption and Decryption Scheme with Diamond Based-PUF

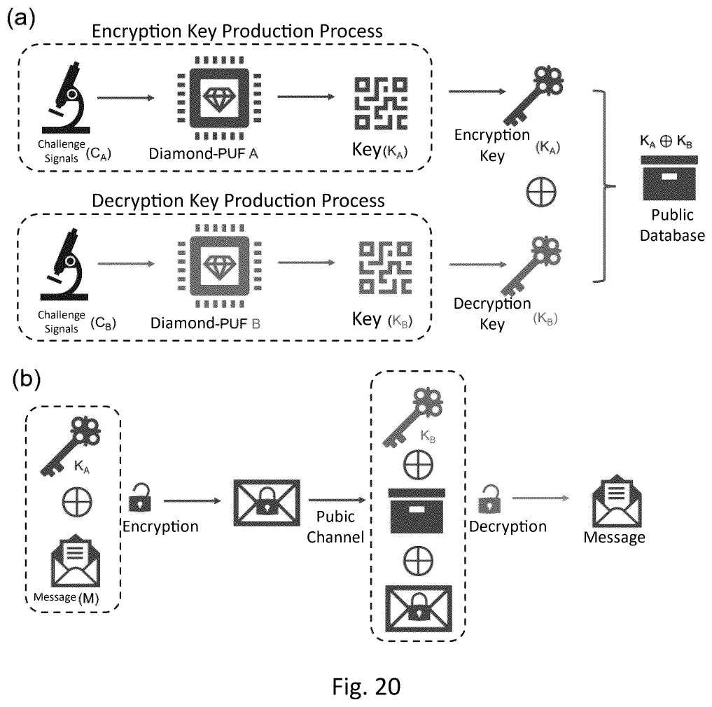

Secure communication between two parties is critical in everyday information security. In some embodiments, the materials of the present invention can be used for security information encryption. FIG. 20 shows a schematic diagram of an information encryption and decryption method, wherein (a) shows the step of generating encryption and decryption keys; (b) shows the step of information encryption and decryption.

First, two unique diamond-PUFs (A and B) are used to generate random secret keys (K_{A} and K_{B}), which belong to the encryption and decryption parties respectively. The two keys are then combined and stored in a public database (K_{A} ⊕K_{B}). In the information encryption stage, the diamond-PUF key K_{A} is used to encrypt the message (M) to generate the ciphertext (M⊕K_{A}), which is then transmitted to the decryption end through public channels. During the information decryption process, the diamond-PUF key K_{B} is used to decrypt the ciphertext by combining the public key from the public database with the key K_{B}, that is, K_{B} ⊕(K_{A} ⊕K_{B}) ⊕(M⊕K_{A})=M. Due to the uniqueness and non-replicability of diamond-PUF labels, there is no need for key sharing and storage during encryption and decryption, ensuring efficient and secure information communication.

The above embodiments are only preferred embodiments of the present invention and do not limit the present invention in any way. Without departing from the scope of the technical solution of the present invention, any form of equivalent substitution or modification or other changes made by any person skilled in the art to the technical solution and technical content disclosed in the present invention does not depart from the technical solution of the present invention and still belongs to the scope of the technical solution of the present invention, within the protection scope of the present invention.

1. A nanodiamond particles based physical unclonable functional material, wherein the physical unclonable functional material comprising: a monocrystalline silicon substrate having nanodiamond particles with silicon vacancy color centers grown in situ thereon.

2. The physical unclonable functional material according to claim 1, wherein the nanodiamond particles with silicon vacancy color centers are grown on the monocrystalline silicon substrate by a chemical vapor deposition method, and wherein in the chemical vapor deposition method, nanodiamond particles treated with salt-assisted air oxidation are use as seed crystals.

3. The physical unclonable functional material according to claim 2, wherein the salt-assisted air oxidation treatment comprises mixing nanodiamond particles and soluble salts, and heating in the air at 200-900° C. for 1 minute to 24 hours, wherein the soluble salt comprises sodium chloride, and wherein the nanodiamond particles and the soluble have a mass ratio of 1:0.1˜10.

4. The physical unclonable functional material according to claim 1, wherein the nanodiamond particles have a particle size of 50 to 100,000 nm, and in particular 100 to 10,000 nm.

5. The physical unclonable functional material according to claim 2, wherein the nanodiamond used as the chemical vapor deposition seed crystal has a particle size of 1 to 500 nm, and in particular 5 to 100 nm.

6. The physical unclonable functional material according to claim 1, wherein the substrate is a monocrystalline silicon substrate, and wherein the nanodiamond particles are adapted to cover 0.1%˜100% surface of the monocrystalline silicon substrate, and in particular 10 to 50%.

7. A preparation method for a nanodiamond particles based physical unclonable functional material, wherein the method comprises the steps of:
(1) treating the nanodiamond particles with salt-assisted air oxidation;
(2) making a seed crystal suspension with the treated nanodiamond particles;
(3) applying the seed crystal suspension to the surface of a monocrystalline silicon substrate to form seed crystals, and applying chemical vapor deposition to grow nanodiamond particles with silicon vacancy color centers.

8. The preparation method according to claim 7, wherein the salt-assisted air oxidation treatment comprises mixing nanodiamond particles with a soluble salt and heating in the air at 200-900° C. for 1 minute to 24 hours, wherein the soluble salt comprises sodium chloride; wherein the soluble salt comprises sodium chloride, wherein the nanodiamond particles and the soluble have a mass ratio of 1:0.1˜10; wherein the seed crystal suspension comprises one or a combination of dimethyl sulfoxide, absolute ethanol, acetone, or water as a dispersion solvent.

9. The preparation method according to claim 7, wherein said step (3) comprises treating the monocrystalline silicon substrate with hydrogen plasma before the growth of nanodiamond particles, wherein treatment conditions comprise: power being 100˜2000 W, chamber pressure being 0.1˜100 torr, flow capacity of hydrogen gas being 5˜1000 sccm, and treatment time being 1 to 60 minutes.

10. The preparation method according to claim 7, wherein said step (3) comprises chemical vapor deposition growth conditions of: spin coating the seed crystal suspension on a pretreated silicon substrate surface repeatedly for 1 to 30 times; subjecting a spin-coated silicon substrate into chemical vapor deposition equipment to deposit and grow nanodiamond particles; wherein the equipment comprises 500˜5000 W of microwave power, 0.1˜100 torr of chamber pressure, 400˜1000° C. of growth temperature, 100-1000 sccm of hydrogen gas flow rate, 1-100 sccm of methane gas flow rate, and 10-120 minutes of growth time.

11. The preparation method according to claim 7, wherein the preparation method further comprises a step (4): heating generated nanodiamond particles in air, wherein a temperature of heating is between 400 and 800° C., more particularly 550 to 650° C.; wherein a heating time is between 1 minute and 24 hours, more particularly 10 minutes to 4 hours, most particularly 30 to 90 minutes.

12. The application of nanodiamond particles with silicon vacancy color centers in physical unclonable functional materials, wherein the physical unclonable functional materials comprise: a monocrystalline silicon substrate and nanodiamond particles with silicon vacancy color centers grown in situ thereon.

13. The application according to claim 12, wherein the nanodiamond particles with silicon vacancy color centers are grown on the monocrystalline silicon substrate by a chemical vapor deposition method, wherein in the chemical vapor deposition method, nanodiamond particles treated with salt-assisted air oxidization are used as seed crystals.

14. A physical unclonable functional label, comprising either a nanodiamond particles based physical unclonable functional material including a monocrystalline silicon substrate having nanodiamond particles with silicon vacancy color centers grown in situ thereon or a nanodiamond particles based physical unclonable functional material prepared according to a preparation method including the steps of:
(1) treating nanodiamond particles with salt-assisted air oxidation;
(2) making a seed crystal suspension with the treated nanodiamond particles;
(3) applying the seed crystal suspension to the surface of a monocrystalline silicon substrate to form seed crystals, and applying chemical vapor deposition to grow nanodiamond particles with silicon vacancy color centers.
